(19) United States
(12) Patent Application Publication
(10) Pub. No.: US 2026/0213777 A1
(43) Pub. Date: Jul. 23, 2026

(54) RECEIVER AND ELECTRONIC DEVICE INCLUDING THE SAME

(71) Applicant: SAMSUNG ELECTRONICS CO., LTD., Suwon-si (KR)

(72) Inventors: Sungbeom KIM, Suwon-si (KR); Sinyoung KIM, Suwon-si (KR); WAN KIM, Suwon-si (KR); HYUNGI SEOK, Suwon-si (KR)

(73) Assignee: SAMSUNG ELECTRONICS CO., LTD., Suwon-si (KR)

(21) Appl. No.: 19/448,480

(22) Filed: Jan. 14, 2026

(30) Foreign Application Priority Data
Jan. 21, 2025 (KR) 10-2025-0009047

(51) Int. Cl. H04B 1/00; H04B 1/30

(52) U.S. Cl. CPC H04B 1/0096; H04B 1/30; H04B 2001/307

(57) ABSTRACT

A receiver includes a low noise amplifier, a gain stage circuit, a first mixer coupled to the gain stage circuit through a first node and that performs frequency down conversion, based on a first local oscillator (LO) signal and a second LO signal inverted from the first LO signal, a second mixer coupled to the gain stage circuit through a second node and that performs frequency down conversion, based on a third LO signal orthogonal to the first LO signal and a fourth LO signal inverted from the third LO signal, a first sink switch coupled to the first node and turned on based on a first control signal defined as a sum of the third and fourth LO signals, and a second sink switch coupled to the second node and turned on based on a second control signal defined as a sum of the first and second LO signals.

### CROSS-REFERENCE TO RELATED APPLICATION

This application claims priority under 35 U.S.C. § 119 to Korean Patent Application No. 10-2025-0009047 filed on Jan. 21, 2025, in the Korean Intellectual Property Office, the disclosure of which being incorporated by reference herein in its entirety.

### BACKGROUND

Embodiments of the present disclosure described herein relate to a receiver and an electronic device including the same.

Radio frequency (RF) receivers used in various wireless communication standards such as cellular, Wi-Fi, Bluetooth, and ultra wideband (UWB) include various forms of amplification to improve the sensitivity of the received signal.

Due to the amplification, a high gain for the received signal may be provided, and improved isolation for in-phase/quadrature (I/Q) crosstalk that may exist may be provided. However, there is an issue that nonlinear components may occur in the amplified output.

### SUMMARY

It is an aspect to provide a receiver with improved linearity and an electronic device including the same.

According to an aspect of one or more embodiments, a receiver may include a low noise amplifier; a gain stage circuit configured to amplify an output of the low noise amplifier; a first mixer coupled to the gain stage circuit through a first node and configured to perform frequency down conversion on an output of the gain stage circuit, based on a first local oscillator (LO) signal and a second LO signal inverted from the first LO signal; a second mixer coupled to the gain stage circuit through a second node and configured to perform frequency down conversion on the output of the gain stage circuit, based on a third LO signal orthogonal to the first LO signal and a fourth LO signal inverted from the third LO signal; a first sink switch coupled to the first node and configured to be turned on based on a first control signal defined as a sum of the third LO signal and the fourth LO signal; and a second sink switch coupled to the second node and configured to be turned on based on a second control signal defined as a sum of the first LO signal and the second LO signal.

According to another aspect of one or more embodiments, a receiver may include a low noise amplifier; a gain stage circuit configured to amplify an output of the low noise amplifier; a mixer coupled to the gain stage circuit through a node and configured to perform frequency down conversion on an output of the gain stage circuit, based on a first local oscillator (LO) signal and a second LO signal inverted from the first LO signal; and a sink switch coupled to the node and configured to be turned on based on a control signal that is complementary to the first LO signal and the second LO signal.

According to yet another aspect of one or more embodiments, an electronic device may include one or more receiving antennas configured to receive one or more first signals; a reception circuit configured to convert the one or more first signals into a baseband signal; and a processor configured to process the baseband signal in a digital domain. The reception circuit includes a low noise amplifier configured to receive the one or more first signals and amplify the one or more first signals; a gain stage circuit configured to amplify an output of the low noise amplifier; a mixer coupled to the gain stage circuit through a node and configured to perform frequency down conversion on an output of the gain stage circuit, based on a first local oscillator (LO) signal and a second LO signal inverted from the first LO signal; and a sink switch coupled to the node and configured to be turned on based on a control signal that is complementary to the first LO signal and the second LO signal.

### BRIEF DESCRIPTION OF THE FIGURES

The above and other aspects will become apparent by describing in detail embodiments thereof with reference to the accompanying drawings, in which:

FIG. 1 is a diagram illustrating a receiver, according to some embodiments;

FIG. 2 is a diagram for describing an operation of an “I” path of a receiver of FIG. 1, according to some embodiments;

FIG. 3 is a diagram for describing an operation of an “Q” path of a receiver of FIG. 1, according to some embodiments;

FIG. 4 illustrates comparative power waveforms of an output with respect to a gain stage circuit of example receivers;

FIG. 5 is a circuit diagram of a first sink switch, according to some embodiments;

FIG. 6 is a circuit diagram of a second sink switch, according to some embodiments;

FIG. 7 is a circuit diagram of a transconductance amplifier, according to some embodiments;

FIG. 8 is a circuit diagram of a sink switch and a mixer, according to some embodiments;

FIG. 9 illustrates an analog baseband circuit, according to some embodiments; and

FIG. 10 illustrates an electronic device, according to some embodiments.

### DETAILED DESCRIPTION

Radio frequency (RF) receivers used in various wireless communication standards such as cellular, Wi-Fi, Bluetooth, and ultra wideband (UWB) may include a low noise amplifier (LNA) for low-noise amplification of a received signal and a mixer. In some wireless communication standards, a stage for gain amplification may be additionally configured between the LNA and the mixer to improve the sensitivity of the received signal.

When the stage for gain amplification is additionally configured, a high gain for the received signal may be provided, and improved isolation for the in-phase/quadrature (I/Q) crosstalk that may exist in the mixer may be provided. However, there is a disadvantage in that nonlinear components may occur in the output of the stage for gain amplification.

Various embodiments described below may provide a receiver with improved linearity and an electronic device including the same.

Various embodiments of the present disclosure may be described in detail and clearly to such an extent that an ordinary one in the art easily implements the present disclosure.

Hereinafter, terms (e.g., antennas, radio frequency integrated circuits (RFICs), low noise amplifiers (LNAs), mixers, analog baseband (ABB) circuits, etc.) referring to electronic devices or radio frequency (RF)-related components or products in the present specification are merely examples for convenience of description, and the various embodiments of the present disclosure are not limited to these terms. That is, other terms having equivalent technical meanings may be used for these terms. For example, the RFIC may be replaced with RF chips, RF circuits, RF modules, etc.

Hereinafter, in the present specification, the term ‘coupled’ between components “A” and “B” may include both components “A” and “B” being connected or electrically connected. As used in this specification, a phrase using the form “at least one of A, B, or C” includes within its scope “only A”, “only B”, “only C”, “A and B”, “A and C”, “B and C” and “A, B, and C.” As used in this specification, the terms “first,” “second,” “third,” “fourth”, and variations thereof used herein do not denote any order and/or importance or the like, but rather are used to distinguish one element from another. For example, a “first” element may be designated as a “second” element, and vice versa, without departing from the scope of the present disclosure.

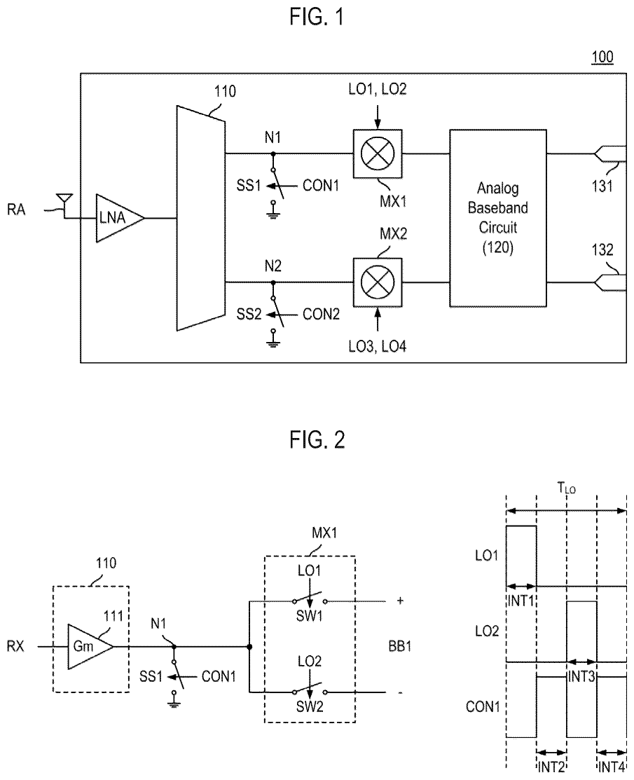

FIG. 1 is a diagram illustrating a receiver, according to some embodiments.

Referring to FIG. 1, a receiver 100 according to some embodiments includes a receiving antenna RA, a low noise amplifier LNA, a gain stage circuit 110, a first mixer MX1, a second mixer MX2, a first sink switch SS1, a second sink switch SS2, an analog baseband circuit 120, a first analog-to-digital converter (ADC) 131, and a second ADC 132. The receiver 100 includes an in-phase “I” path and a quadrature “Q” path, where the I path includes the first mixer MX1, the first sink switch SS1, and the first ADC 131, and the Q path includes the second mixer MX2, the second sink switch SS2, and the second ADC 132. In some embodiments, the low noise amplifier LNA may be configured as a plurality of amplifiers, the gain stage circuit 110 may include a plurality of transconductance amplifiers, and/or the analog baseband circuit 120 may include a plurality of receiving chains. In this case, at least some of the plurality of low noise amplifiers LNA may be included in the I path or the Q path, at least some of the plurality of transconductance amplifiers may be included in the I path or the Q path, or at least some of the plurality of receiving chains may be included in the I path or the Q path.

For convenience, in the embodiment of FIG. 1, the line, wire, and/or channel connected between each configuration is illustrated as being single, but embodiments of the present disclosure are not limited thereto. That is, it will be understood by one of ordinary skill in the art that, in some embodiments, the line, wire, and/or channel may be configured as differential.

The receiving antenna RA is configured to receive a receiving signal transmitted from the outside of the receiver 100. For convenience, FIG. 1 illustrates only one receiving antenna RA, but embodiments of the present disclosure are not limited thereto. According to some embodiments, the receiving antenna RA may be configured in multiple numbers (i.e., a multiple antennas RA).

The low noise amplifier LNA may be configured to receive a received signal from the receiving antenna RA and to amplify the received signal. In particular, the low noise amplifier LNA may amplify the intensity of the received signal while minimizing noise of the received signal. According to some embodiments, when the plurality of receiving antennas RA are configured, the number of low noise amplifiers LNA may be configured as many as the number of receiving antennas RA.

The gain stage circuit 110 may be configured to amplify an output of the low noise amplifier LNA. The gain stage circuit 110 receives an amplified signal from the low noise amplifier LNA, and amplifies the amplified signal according to a gain of the gain stage circuit 110 so as to output the amplified signal with increased gain. For example, the gain stage circuit 110 may include a transconductance amplifier. The transconductance amplifier may amplify a signal based on a transconductance gain “gₘ”. The transconductance amplifier may convert a voltage corresponding to the output of the low noise amplifier LNA into a current. Through the gain stage circuit 110, power loss that may occur in the first mixer MX1 and the second mixer MX2 may be compensated.

The first mixer MX1 is coupled to the gain stage circuit 110 through a first node N1, and the second mixer MX2 is coupled to the gain stage circuit 110 through a second node N2. The first mixer MX1 and the second mixer MX2 receive a local oscillator (LO) signal, and perform a frequency down conversion on a frequency of an amplified signal that is output from the gain stage circuit 110 based on the LO signal.

In particular, the first mixer MX1 performs the frequency down conversion on the output of the gain stage circuit 110 based on a first LO signal LO1 and a second LO signal LO2. In this case, the second LO signal LO2 is a signal inverted from the first LO signal LO1. That is, the first LO signal LO1 and the second LO signal LO2 have a phase difference of 180 degrees. The first LO signal LO1 and the second LO signal LO2 are provided to the first mixer MX1 included in the I path and may be considered “I” signals.

The second mixer MX2 performs the frequency down conversion on the output of the gain stage circuit 110 based on a third LO signal LO3 and a fourth LO signal LO4. In this case, the third LO signal LO3 is orthogonal to the first LO signal LO1, and the fourth LO signal LO4 is a signal inverted from the third LO signal LO3. That is, the third LO signal LO3 and the first LO signal LO1 have a phase difference of 90 degrees, and the third LO signal LO3 and the fourth LO signal LO4 have a phase difference of 180 degrees. The third LO signal LO3 and the fourth LO signal LO4 are provided to the second mixer MX2 included in the Q path and are “Q” signals.

The first to fourth LO signals LO1 to LO4 described above may have a logic high in one of first to fourth consecutive intervals included in a period defined for the first to fourth LO signals LO1 to LO4. For example, the first LO signal LO1 may have a logic high in the first interval, the second LO signal LO2 may have a logic high in the third interval, the third LO signal LO3 may have a logic high in the second interval, and the fourth LO signal LO4 may have a logic high in the fourth interval. Therefore, in terms of duty ratio, the first to fourth LO signals LO1 to LO4 have a duty ratio of 25%.

According to some embodiments, the first mixer MX1 and the second mixer MX2 may be configured as passive mixers. According to some embodiments, the first mixer MX1 and the second mixer MX2 may be configured as balanced mixers or double balanced mixers.

The first sink switch SS1 is coupled to the first node N1, and the second sink switch SS2 is coupled to the second node N2. The first sink switch SS1 is configured to be turned on or off based on a first control signal CON1. In this case, the first control signal CON1 may be defined as a sum of the third LO signal LO3 and the fourth LO signal LO4. The second sink switch SS2 is configured to be turned on or off based on a second control signal CON2. In this case, the second control signal CON2 is defined as a sum of the first LO signal LO1 and the second LO signal LO2. The first control signal CON1 and the second control signal CON2 each may be generated by one of the processor 210, the RFIC 220, or the reception circuit 222.

According to the above-described embodiments, the first control signal CON1 and the second control signal CON2 are complementary to each other or have a phase difference of 180 degrees. Therefore, the first sink switch SS1 and the second sink switch SS2 operate complementary to each other. In other words, when the first sink switch SS1 is turned on, the second sink switch SS2 is turned off, and when the second sink switch SS2 is turned on, the first sink switch SS1 is turned off.

The first sink switch SS1 operates complementarily with the first mixer MX1, and the second sink switch SS2 operates complementarily with the second mixer MX2. That is, in an interval in which the first mixer MX1 performs the frequency down conversion based on the first LO signal LO1 and in an interval in which the first mixer MX1 performs the frequency down conversion based on the second LO signal LO2, the first sink switch SS1 is turned off. In contrast, in an interval in which the first mixer MX1 does not perform the frequency down conversion, the first sink switch SS1 is turned on.

As in the above description, in an interval in which the second mixer MX2 performs the frequency down conversion based on the third LO signal LO3 and in an interval in which the second mixer MX2 performs the frequency down conversion based on the fourth LO signal LO4, the second sink switch SS2 is turned off. In contrast, in an interval in which the second mixer MX2 does not perform the frequency down conversion, the second sink switch SS2 is turned on.

Looking at the I path, in an interval in which both the first LO signal LO1 and the second LO signal LO2 are at a logic low, i.e., in the interval in which the first mixer MX1 is turned off, a nonlinear component may occur in a signal (i.e., the output of the gain stage circuit 110) corresponding to the first node N1. The first sink switch SS1 may be turned on in the interval in which the first mixer MX1 is turned off, thereby providing a ground path with respect to the first node N1.

Looking at the Q path, in an interval in which both the third LO signal LO3 and the fourth LO signal LO4 are at a logic low, i.e., in the interval in which the second mixer MX2 is turned off, a nonlinear component may occur in a signal (i.e., the output of the gain stage circuit 110) corresponding to the second node N2. The second sink switch SS2 may be turned on in the interval in which the second mixer MX2 is turned off, thereby providing a ground path with respect to the second node N2.

The analog baseband circuit 120 is configured to process the output of the first mixer MX1 and the second mixer MX2, i.e., the baseband signal corresponding to the frequency down conversion. In some embodiments, the analog baseband circuit 120 may be configured to perform at least one of buffering, filtering, power distribution, or signal amplification and gain control.

The first ADC 131 and the second ADC 132 are configured to perform analog to digital (AD) conversion on the baseband signal. The first ADC 131 performs AD conversion on the baseband signal output from the first mixer MX1, and the second ADC 132 performs AD conversion on the baseband signal output from the second mixer MX2. Through AD conversion, the baseband signal may be converted into a digital signal.

The receiver 100 according to the above-described embodiments provides the ground path for the first node N1 and the second node N2 respectively through the first sink switch SS1 and the second sink switch SS2 configured respectively between the gain stage circuit 110 and the first mixer MX1 and the second mixer MX2, thereby minimizing the occurrence of nonlinear components and the influence of the nonlinear components in the receiver 100 in the interval in which each mixer is turned off, and improving an input intercept point (IIP) performance and a linearity of the receiver 100.

FIG. 2 is a diagram for describing an operation of an “I” path of a receiver of FIG. 1, according to some embodiments.

Referring to FIG. 2, the gain stage circuit 110 according to some embodiments may include a first transconductance amplifier 111 included in the I path. The first transconductance amplifier 111 is coupled to the first node N1 and is included in the I path.

The first mixer MX1 may include a first switch SW1 that is turned on according to the first LO signal LO1 and a second switch SW2 that is turned on according to the second LO signal LO2. The first switch SW1 and the second switch SW2 down-convert the frequency of a signal obtained by amplifying a receiving signal RX through the first transconductance amplifier 111 by the frequency of the first LO signal LO1 and the second LO signal LO2. According to the down conversion, a first baseband signal BB1 is output.

The first LO signal LO1 that operates the first switch SW1 may be defined by the following Equation 1.

$${S}_{I +} ( t ) = \{ \begin{matrix}1 & {kT}_{LO} \leq ( k + 0.25 ) {T}_{LO} , k ∈ Z \\ 0 & ( K + 0.25 ) {T}_{LO} \leq t \leq ( k + 1 ) {T}_{LO} , k ∈ Z\end{matrix} \qquad [ Equation 1 ]$$

Here, S_{I+}(t) is the first LO signal LO1, “k” is an integer belonging to an integer set “Z”, and T_{LO} is the period of the first to fourth LO signals LO1 to LO4. The first LO signal LO1 has a logic high in a first interval INT1 within the period T_{LO}, and has a logic low in the remaining intervals.

The second LO signal LO2 that operates the second switch SW2 may be defined by the following Equation 2.

$${S}_{I -} ( t ) = {S}_{I +} ( t - \frac{{T}_{LO}}{2} ) \qquad [ Equation 2 ]$$

The second LO signal LO2 is the first LO signal LO1 shifted by T_{LO}/2 (i.e., 180 degrees) on a time domain. The second LO signal LO2 has a logic high in a third interval INT3 within the period T_{LO}, and has a logic low in the remaining intervals.

The first control signal CON1 for operating the first sink switch SS1 is defined as the sum of the third LO signal LO3 and the fourth LO signal LO4. The third LO signal LO3 may be defined by the following Equation 3.

$${S}_{Q +} ( t ) = {S}_{I +} ( t - \frac{{T}_{LO}}{4} ) \qquad [ Equation 3 ]$$

The third LO signal LO3 is the first LO signal LO1 shifted by T_{LO}/4 (i.e., 90 degrees) on the time domain. The third LO signal LO3 has a logic high in a second interval INT2 and has a logic low in the remaining intervals.

The fourth LO signal LO4 may be defined by the following Equation 4.

$${S}_{Q -} ( t ) = {S}_{I +} ( t - \frac{3 {T}_{LO}}{4} ) \qquad [ Equation 4 ]$$

That is, the fourth LO signal LO4 is the first LO signal LO1 shifted by 3T_{LO}/4 (270 degrees) on the time domain. The fourth LO signal LO4 has a logic high in a fourth interval INT4 and has a logic low in the remaining intervals.

The Fourier series of the first LO signal LO1 according to Equation 1 is defined by the following Equation 5.

$${S}_{I +} ( t ) = {\sum }_{n = - ∞}^{∞} {( + 1 )}^{n} \cdot {a}_{n} \cdot {e}^{jn {ω}_{LO} t} \qquad [ Equation 5 ]$$

Here,

$${a}_{n} = \frac{1}{4} \cdot {e}^{- jn \frac{π}{4}} \cdot sin c ( \frac{n π}{4} ) ,$$

and ω_{LO} is a fundamental frequency.

The Fourier series of the second LO signal LO2 according to Equation 2 is defined by Equation 6 below, the Fourier series of the third LO signal LO3 according to Equation 3 is defined by Equation 7 below, and the Fourier series of the fourth LO signal LO4 according to Equation 4 is defined by Equation 8 below.

$${S}_{I -} ( t ) = {\sum }_{n = - ∞}^{∞} {( - 1 )}^{n} \cdot {a}_{n} \cdot {e}^{jn {ω}_{LO} t} \qquad [ Equation 6 ]$$

$${S}_{Q +} ( t ) = {\sum }_{n = - ∞}^{∞} {e}^{- jn \frac{π}{2}} \cdot {a}_{n} \cdot {e}^{jn {ω}_{LO} t} \qquad [ Equation 7 ]$$

$${S}_{Q -} ( t ) = {\sum }_{n = - ∞}^{∞} {e}^{+ jn \frac{π}{2}} \cdot {a}_{n} \cdot {e}^{jn {ω}_{LO} t} \qquad [ Equation 8 ]$$

Below, an operation of removing a term that causes a nonlinear component from a voltage V_{RF} output to the first node N1 through the first sink switch SS1 is described in detail. When the voltage V_{RF} output to the first node N1 is defined based on the Equations 1 to 4 described above, the voltage V_{RF} is defined by the following Equation 9.

$${V}_{RF} ( t ) = ( {S}_{I +} ( t ) + {S}_{I -} ( t ) ) {R}_{SW} \cdot {i}_{RF} ( t ) + ( {S}_{Q +} ( t ) + {S}_{Q -} ( t ) ) {R}_{OFF} \cdot {i}_{RF} ( t ) + {S}_{I +} ( t ) \cdot \{ [ {S}_{I +} ( t ) \cdot {i}_{RF} ( t ) ] * {z}_{BB} ( t ) \} + {S}_{I -} ( t ) \cdot \{ [ {S}_{I -} ( t ) \cdot {i}_{RF} ( t ) ] * {z}_{BB} ( t ) \} = {R}_{SW} \cdot {i}_{RF} ( t ) + ( {S}_{Q +} ( t ) + {S}_{Q -} ( t ) ) ( {R}_{OFF} - {R}_{SW} ) \cdot {I}_{RF} ( t ) + {S}_{I +} ( t ) \cdot \{ [ {S}_{I +} ( t ) \cdot {i}_{RF} ( t ) ] * {z}_{BB} ( t ) \} + {S}_{I -} ( t ) \cdot \{ [ {S}_{I -} ( t ) \cdot {i}_{RF} ( t ) ] * {z}_{BB} ( t ) \} \qquad [ Equation 9 ]$$

Here, R_{SW} is an equivalent resistance of the first mixer MX1 when the first mixer MX1 is turned on, i_{RF} is an input signal (or current) of the first transconductance amplifier 111, and R_{OFF} is an equivalent resistance of the first mixer MX1 when the first mixer MX1 is turned off. ZBB is an equivalent impedance connected to an output terminal of the first mixer MX1.

In Equation 9, V_{X}, which is an item generated in the interval in which both the first switch SW1 and the second switch SW2 are turned off, may be defined as Equation 10 below.

$${V}_{X} ( t ) = ( {S}_{Q +} ( t ) + {S}_{Q -} ( t ) ) ( {R}_{OFF} - {R}_{S W} ) \cdot {i}_{RF} ( t ) \qquad [ Equation 10 ]$$

When V_{X} of Equation 10 is Fourier transformed based on Equations 5 to 8 described above, V_{X} may be defined by the following Equation 11.

$${V}_{X} ( ω ) = ( {R}_{OFF} - {R}_{SW} ) {\sum }_{n = - ∞}^{∞} ( {e}^{- jn \frac{π}{2}} + {e}^{+ jn \frac{π}{2}} ) \cdot {a}_{n} \cdot {i}_{RF} ( ω - n {ω}_{LO} ) \qquad [ Equation 11 ]$$

When the frequency “w” of Equation 11 is ω=(2k+1)ω_{LO}±ωₘ (where “k” is an integer and wₘ is a modulation frequency), Vx of Equation 11 may be defined by Equation 12 below.

$${V}_{X} ( ( 2 k + 1 ) {ω}_{LO} \pm {ω}_{m} ) = ( {R}_{OFF} - {R}_{SW} ) \text{} {\sum }_{n = - ∞}^{∞} ( {e}^{- jn \frac{π}{2}} + {e}^{+ jn \frac{π}{2}} ) \cdot {a}_{n} \cdot {i}_{RF} ( ( 2 k - n + 1 ) {ω}_{LO} \pm {ω}_{m} ) \qquad [ Equation 12 ]$$

As in Equation 12, when the frequency “w” is ω=(2k+1)ω_{LO}±ωₘ,

$$( {e}^{- jn \frac{π}{2}} + {e}^{+ jn \frac{π}{2}} )$$

(where “n” is an even integer) component exists, so V_{X}((2k+1)ω_{LO}±ωₘ) may have a relatively large value. For example, when both “k” and “n” are “0”, V_{X}((2k+1)ω_{LO}±ωₘ) is expressed as 2·(R_{OFF}−R_{SW})·a₀·i_{RF} (ω_{LO}±ωₘ) below. That is, V_{X}(2k+1)ω_{LO}±ωₘ) has a value for a valid input current (i_{RF} (ω_{LO}±ωₘ). In this case, V_{X}((2k+1)ω_{LO}±ωₘ) may have a large value due to R_{OFF}.

V_{X}((2k+1)ω_{LO}±ωₘ) may cause nonlinear components, intermodulation (IMD) 2 and IMD 3, with respect to the first mixer MX1. As examined, V_{X}((2k+1)ω_{LO}±ωₘ) is related to R_{OFF}, so the first sink switch SS1 operates to remove V_{X}((2k+1)ω_{LO}±ωₘ) in the turn-off interval of the first mixer MX1 where R_{OFF} occurs.

In detail, the first sink switch SS1 is turned on when the first control signal CON1, which is complementarily defined with the first LO signal LO1 and the second LO signal LO2, is a logic high. That is, the first sink switch SS1 is turned on in the second interval INT2 and the fourth interval INT4, and turned off in the first interval INT1 and the third interval INT3. The first sink switch SS1 grounds the first node N1 based on being turned on. Since the first node N1 is grounded, the V_{RF} when the first mixer MX1 is turned off is sinked to the ground. As a result, V_{X}((2k+1)ω_{LO}+ωₘ) associated with the R_{OFF} may be removed through the first sink switch SS1.

Even if the first sink switch SS1 is configured between the first transconductance amplifier 111 and the first mixer MX1, the gain and noise figure performance may be maintained.

According to the embodiments described above, the first sink switch SS1 of the present disclosure may minimize a nonlinear component of the first baseband signal BB1 and may improve the linearity while maintaining the gain and noise figure performance by removing an item causing a nonlinear component from the V_{RF} in the turn-off interval of the first mixer MX1.

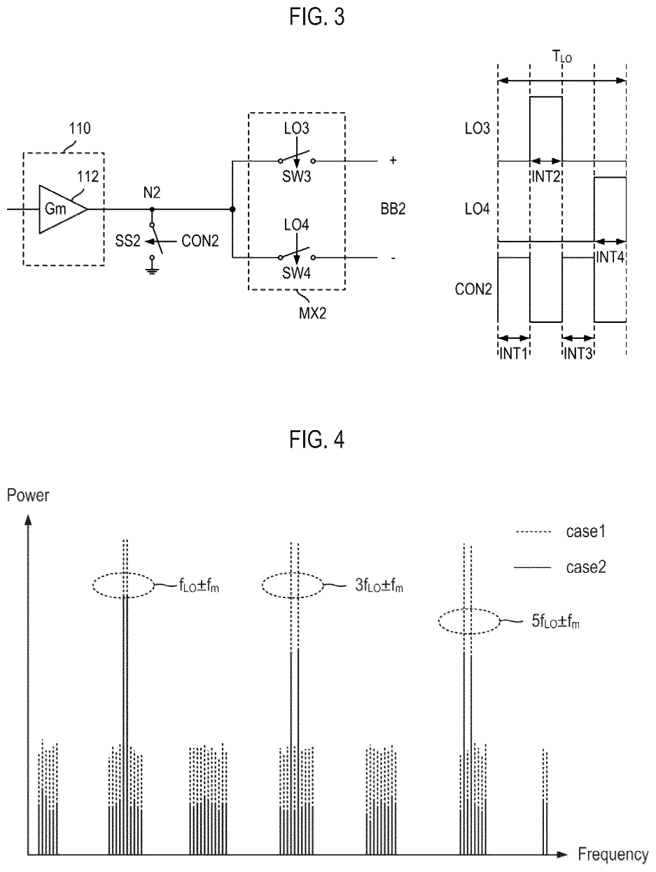

FIG. 3 is a diagram for describing an operation of a “Q” path of a receiver of FIG. 1, according to some embodiments. Hereinafter, additional descriptions of parts overlapping with the above-described FIG. 2 will be omitted to avoid redundancy.

Referring to FIG. 3, the gain stage circuit 110 according to some embodiments may include a second transconductance amplifier 112 included in the Q path. The second transconductance amplifier 112 is coupled to the second node N2 and is included in the Q path.

The second mixer MX2 may include a third switch SW3 that is turned on according to the third LO signal LO3 and a fourth switch SW4 that is turned on according to the fourth LO signal LO4. The third switch SW3 and the fourth switch SW4 down-convert the frequency of a signal obtained by amplifying the receiving signal RX through the second transconductance amplifier 112 by the frequency of the third LO signal LO3 and the fourth LO signal LO4. According to the down conversion, a second baseband signal BB2 is output.

The second control signal CON2 for operating the second sink switch SS2 is defined as the sum of the first LO signal LO1 and the second LO signal LO2. That is, the second control signal CON2 is defined complementarily with the third LO signal LO3 and the fourth LO signal LO4.

The voltage output to the second node N2 includes items generated in the interval in which both the third switch SW3 and the fourth switch SW4 are turned off. In Equation 9 defining the voltage V_{RF} output to the first node N1 described above, the component multiplied by R_{OFF} is the sum of the Fourier series of the third LO signal LO3 and the fourth LO signal LO4 defined according to Equations 7 and 8, but the component multiplied by R_{OFF} in the voltage of the second node N2 is the sum of the Fourier series of the first LO signal LO1 and the second LO signal LO2 defined according to Equations 5 and 6.

As in the above description, the Equation 10 defining V_{X} causing a nonlinear component in the voltage of the first node N1 will include the sum of the Fourier series of the third LO signal LO3 and the fourth LO signal LO4, but the item causing a nonlinear component in the voltage of the second node N2 will include the sum of the Fourier series of the first LO signal LO1 and the second LO signal LO2. In the case of the Q path, an item causing a nonlinear component will occur in the interval where the second mixer MX2 is turned off according to the first LO signal LO1 and the second LO signal LO2.

The second sink switch SS2 operates to remove V_{X}((2k+1)ω_{LO}±ωₘ) in the turn-off interval of the second mixer MX2 where R_{OFF} occurs. In detail, the second sink switch SS2 is turned on when the second control signal CON2 is a logic high. That is, the second sink switch SS2 is turned on in the first interval INT1 and the third interval INT3, and is turned off in the second interval INT2 and the fourth interval INT4. The second sink switch SS2 grounds the second node N2 based on being turned on. Since the second node N2 is grounded, the voltage of the second node N2 when the second mixer MX2 is turned off is sinked to the ground. As a result, V_{X}(2k+1)ω_{LO}±ωₘ) associated with the R_{OFF} may be removed through the second sink switch SS2.

Even if the second sink switch SS2 is configured between the second transconductance amplifier 112 and the second mixer MX2, the gain and noise figure performance may be maintained.

According to the embodiments described above, the second sink switch SS2 of the present disclosure may minimize the nonlinear component of the second baseband signal BB2 while maintaining the gain and noise figure performance by removing the item causing the nonlinear component in the turn-off interval of the second mixer MX2.

FIG. 4 illustrates comparative power waveforms of an output with respect to a gain stage circuit of example receivers. In FIG. 4, Case 1 is a waveform for a receiver in which a sink switch is not configured between a gain stage circuit and a mixer, and Case 2 is a waveform for a receiver in which a sink switch is configured between the gain stage circuit 110 and the mixer MX1 or MX2 according to the embodiments described above.

Referring to FIG. 4, in the frequency intervals (k=0, 1, 2) corresponding to V_{X}((2k+1)ω_{LO}±ωₘ), it may be confirmed that a size of the power according to the V_{X}((2k+1)ω_{LO}±ωₘ) component is relatively reduced in Case 2, as compared to Case 1 in which there is no sink switch. Therefore, in the case of Case 2, since the V_{X}((2k+1)ω_{LO}±ωₘ) component affecting the IMD2/3 component, which is a nonlinear component, is greatly reduced in the output of the gain stage circuit 110, an input intercept point (IIP) 2/3 performance may be improved.

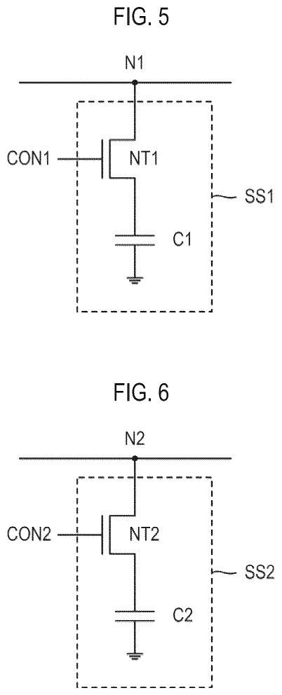

FIG. 5 is a circuit diagram of a first sink switch, according to some embodiments, and FIG. 6 is a circuit diagram of a second sink switch, according to some embodiments.

Referring to FIG. 5, the first sink switch SS1 according to some embodiments may include a first capacitor C1 and a first N-type transistor NT1.

The first capacitor C1 includes a first terminal coupled to the first N-type transistor NT1, and a second terminal coupled to ground. The first capacitor C1 may provide an alternating current (AC) short with respect to the first node N1. In detail, the first capacitor C1 may provide a direct current (DC) bias with respect to the first mixer MX1 by providing the AC short with respect to the first node N1. Accordingly, flicker noise of the first mixer MX1 may be prevented.

The first N-type transistor NT1 includes a first drain coupled to the first node N1, a first source coupled to the first terminal of the first capacitor C1, and a first gate to which the first control signal CON1 is provided. According to the first control signal CON1, the first N-type transistor NT1 is turned on in the second interval INT2 and the fourth interval INT4. By turning on the first N-type transistor NT1, a sink for the first node N1 may be provided as described above.

Referring to FIG. 6, the second sink switch SS2 according to some embodiments may include a second capacitor C2 and a second N-type transistor NT2.

The second capacitor C2 includes a third terminal coupled to the second N-type transistor NT2, and a fourth terminal coupled to ground. The second capacitor C2 provides an AC short for the second node N2, so that flicker noise of the second mixer MX2 may be prevented.

The second N-type transistor NT2 includes a second drain coupled to the second node N2, a second source coupled to the third terminal of the second capacitor C2, and a second gate to which the second control signal CON2 is provided. According to the second control signal CON2, the second N-type transistor NT2 is turned on in the first interval INT1 and the third interval INT3. By turning on the second N-type transistor NT2, a sink for the second node N2 may be provided as described above.

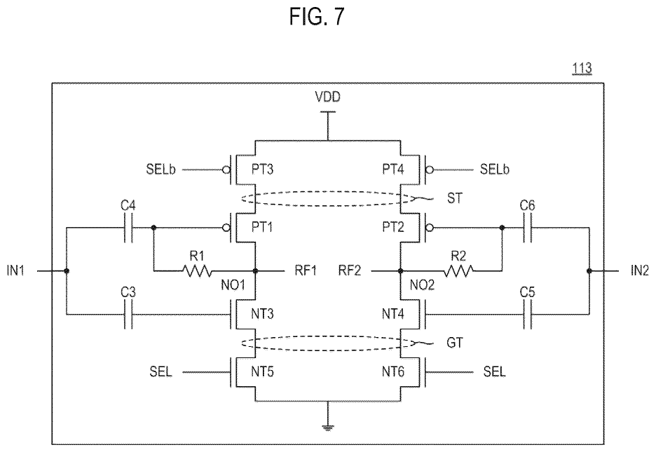

FIG. 7 is a circuit diagram of a transconductance amplifier, according to some embodiments. Although FIG. 7 illustrates that the transconductance amplifier is configured based on a differential signal, the transconductance amplifier according to embodiments of the present disclosure is not limited to the configuration illustrated in FIG. 7. That is, one of ordinary skill in the art will understand that, in some embodiments, the transconductance amplifier may be configured based on a single-ended signal.

Referring to FIG. 7, a transconductance amplifier 113 according to some embodiments may correspond to the first transconductance amplifier 111 of FIG. 2 and the second transconductance amplifier 112 of FIG. 3 described above. The transconductance amplifier 113 may include a pair of inverters (e.g., two inverters), a pair of N-type transistors NT5 and NT6, and a pair of P-type transistors PT3 and PT4.

The pair of inverters may respectively receive differential input signals IN1 and IN2 and may respectively output differential RF signals RF1 and RF2 that correspond respectively to the differential input signals IN1 and IN2 to a first output node NO1 and a second output node NO2, respectively. The differential input signals IN1 and IN2 may correspond to the output of the low noise amplifier LNA according to the above-described embodiments. The differential RF signals RF1 and RF2 may correspond to the output of the transconductance amplifier 113. One of the first output node NO1 or the second output node NO2 may be coupled to the first node N1 or the second node N2 described above.

The pair of inverters includes a ground terminal GT for pull down and a supply terminal ST for pull up. The pair of inverters includes a first inverter including a third N-type transistor NT3 and a first P-type transistor PT1, and a second inverter including a fourth N-type transistor NT4 and a second P-type transistor PT2.

In the first inverter, the third N-type transistor NT3 includes a drain coupled to the first output node NO1, a gate coupled to a third capacitor C3, and a source coupled to the ground terminal GT. The first P-type transistor PT1 includes a source coupled to the supply terminal ST, a gate coupled to a fourth capacitor C4, and a drain coupled to the first output node NO1. A first resistor R1 is coupled to the first output node NO1 and the gate of the first P-type transistor PT1.

The third capacitor C3 and the fourth capacitor C4 provide AC coupling with respect to the first input signal IN1.

In the second inverter, the fourth N-type transistor NT4 has a drain coupled to the second output node NO2, a gate coupled to a fifth capacitor C5, and a source coupled to the ground terminal GT. The second P-type transistor PT2 includes a source coupled to the supply terminal ST, a gate coupled to a sixth capacitor C6, and a drain coupled to the second output node NO2. A second resistor R2 is coupled to the second output node NO2 and the gate of the second P-type transistor PT2.

The fifth capacitor C5 and the sixth capacitor C6 provide AC coupling with respect to the second input signal IN2.

Each of N-type transistors NT5 and NT6 includes a first drain coupled to the ground terminal GT, a first gate to which a selection signal SEL is provided, and a first source that is grounded. The N-type transistors NT5 and NT6 are turned on or off depending on the selection signal SEL, thereby adjusting the gain of the transconductance amplifier 113. The selection signal SEL may selectively turn on or off the fifth N-type transistor NT5 and the sixth N-type transistor NT6. For example, the selection signal SEL may include as many bits as the number of N-type transistors to which the selection signal SEL is applied.

Each of P-type transistors PT3 and PT4 includes a second drain coupled to the supply terminal ST, a second gate to which an inverted selection signal SELb is provided, which is inverted from the selection signal SEL, and a second source to which a supply voltage VDD is provided. The P-type transistors PT3 and PT4 are turned on or off depending on the inverted selection signal SELb, thereby adjusting the gain of the transconductance amplifier 113. The inverted selection signal SELb may selectively turn on or off the third P-type transistor PT3 and the fourth P-type transistor PT4. For example, the inverted selection signal SELb may include as many bits as the number of P-type transistors to which the inverted selection signal SELb is applied.

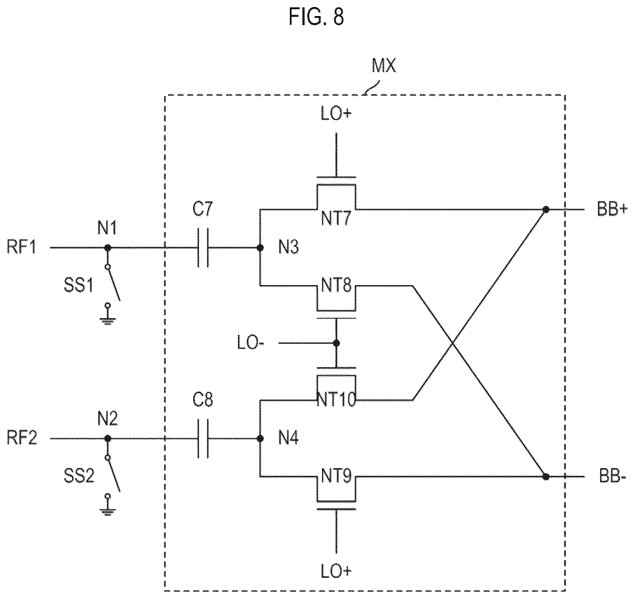

FIG. 8 is a circuit diagram of a sink switch and a mixer, according to some embodiments. Although FIG. 8 illustrates that the mixer is configured based on a differential signal, the mixer according to embodiments of the present disclosure is not limited to the structure illustrated in FIG. 8. That is, one of ordinary skill in the art will understand that, in some embodiments, the mixer may also be configured based on a single-ended signal.

Referring to FIG. 8, a mixer MX according to some embodiments may correspond to the first mixer MX1 of FIGS. 1 and 2 and/or the second mixer MX2 of FIGS. 1 and 3 described above. The mixer MX may include a seventh capacitor C7, a seventh N-type transistor NT7, an eighth capacitor C8, an eighth N-type transistor NT8, a ninth N-type transistor NT9, and a tenth N-type transistor NT10.

The seventh capacitor C7 includes a fifth terminal coupled to the first node N1 and a sixth terminal coupled to a third node N3. The seventh capacitor C7 may provide AC coupling with respect to the first RF signal RF1.

The seventh N-type transistor NT7 includes a third drain coupled to the sixth terminal (i.e., the third node N3), a third gate provided with a positive LO signal LO+, and a third source outputting a positive baseband signal BB+ corresponding to the frequency down conversion. The seventh N-type transistor NT7 performs the frequency down conversion on the first RF signal RF1 by being turned on or off depending on the positive LO signal LO+.

The eighth N-type transistor NT8 includes a fourth drain coupled to the sixth terminal (i.e., the third node N3), a fourth gate provided with a negative LO signal LO−, and a fourth source outputting a negative baseband signal BB−. The negative baseband signal BB− may be an inverted signal of the positive baseband signal BB+. The eighth N-type transistor NT8 performs the frequency down conversion on the first RF signal RF1 by being turned on or off depending on the negative LO signal LO−.

The eighth capacitor C8 includes a seventh terminal coupled to the second node N2 and an eighth terminal coupled to a fourth node N4. The eighth capacitor C8 may provide AC coupling with respect to the second RF signal RF2.

The ninth N-type transistor NT9 includes a fifth drain coupled to the eighth terminal (i.e., the fourth node N4), a fifth gate provided with the positive LO signal LO+, and a fifth source outputting the negative baseband signal BB−. The ninth N-type transistor NT9 performs the frequency down conversion on the second RF signal RF2 by being turned on or off depending on the positive LO signal LO+.

The tenth N-type transistor NT10 includes a sixth drain coupled to the eighth terminal (i.e., the fourth node N4), a sixth gate provided with the negative LO signal LO−, and a sixth source outputting the positive baseband signal BB+. The tenth N-type transistor NT10 performs the frequency down conversion on the second RF signal RF2 by being turned on or off depending on the negative LO signal LO−.

In FIG. 8, the positive LO signal LO+ and the negative LO signal LO− may be combinations (e.g., the first LO signal and the second LO signal or the third LO signal and the fourth LO signal) of LO signals having a phase difference of 180 degrees from each other among the first to fourth LO signals described above. The positive baseband signal BB+ and the negative baseband signal BB− may correspond to the first baseband signal or the second baseband signal described above.

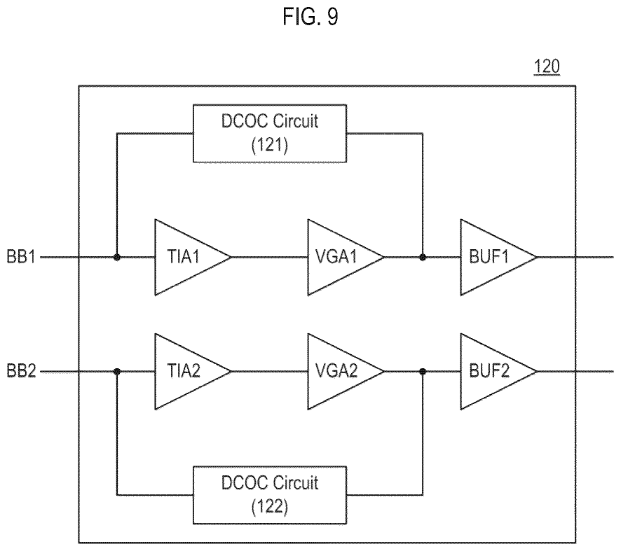

FIG. 9 illustrates an analog baseband circuit, according to some embodiments.

Referring to FIG. 9, the analog baseband circuit 120 according to some embodiments may include a first transimpedance amplifier TIA1, a first variable gain amplifier VGA1, a first buffer BUF1, and a first DC offset cancellation (DCOC) circuit 121, which are included in the I path, and may include a second transimpedance amplifier TIA2, a second variable gain amplifier VGA2, a second buffer BUF2, and a second DCOC circuit 122, which are included in the Q path.

The first transimpedance amplifier TIA1 is configured to receive the first baseband signal BB1 and to provide amplification and current-to-voltage conversion with respect to the first baseband signal BB1. According to some embodiments, a plurality of first transimpedance amplifiers TIA1 may be configured with respect to the I path. The first variable gain amplifier VGA1 is configured to amplify the output of the first transimpedance amplifier TIA1 based on a variable gain. The first buffer BUF1 is configured to buffer the output of the first variable gain amplifier VGA1. The first DCOC circuit 121 is configured to correct or remove a DC offset for the output of the first variable gain amplifier VGA1.

The second transimpedance amplifier TIA2 is configured to receive the second baseband signal BB2 and to provide amplification and current-to-voltage conversion with respect to the second baseband signal BB2. According to some embodiments, the second transimpedance amplifier TIA2 may be configured in multiple units for the Q path. The second variable gain amplifier VGA2 is configured to amplify the output of the second transimpedance amplifier TIA2 based on a variable gain. The second buffer BUF2 is configured to buffer the output of the second variable gain amplifier VGA2. The second DCOC circuit 122 is configured to correct or remove a DC offset for the output of the second variable gain amplifier VGA2.

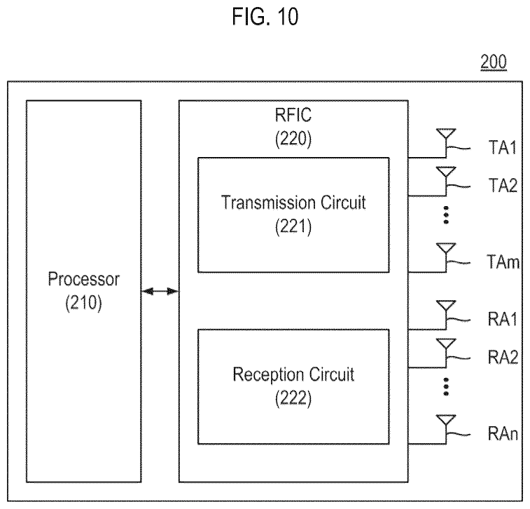

FIG. 10 illustrates an electronic device, according to some embodiments.

Referring to FIG. 10, an electronic device 200 according to some embodiments may include a processor 210, a radio frequency integrated circuit (RFIC) 220, transmitting antennas TA1 to TAm, and receiving antennas RA1 to RAn. For example, the electronic device 200 may be a transceiver. While plural transmitting antennas TA1 to TAm and plural receiving antennas RA1 to RAn are illustrated in FIG. 10, in some embodiments, a single transmitting antenna and/or a single transmitting antenna may be provided.

The processor 210 is configured to process a baseband signal in the digital domain. For example, the processor 210 may obtain, generate, or process a digital signal corresponding to a transmitting signal and may provide the digital signal to the RFIC 220. In some embodiments, the processor 210 may receive a digital signal corresponding to a receiving signal from the RFIC 220 and may process the digital signal to obtain information. In an embodiment, the processor 210 may include a central processing unit (CPU) and/or an application specific integrated circuit (ASIC) coded to implement the functions described above.

In some embodiments, the processor 210 may process the digital signal based on a fast Fourier transform (FFT), a short-time Fourier transform (STFT), a 2D and/or 3D FFT, etc.

In some embodiments, the processor 210 may detect a target through a constant false alarm rate (CFAR) for a digital signal corresponding to a receiving signal. The CFAR denotes an algorithm for uniformly setting a false alarm, which determines that there is a reflection signal for a target even though there is no reflection signal for the target due to a noise level that fluctuates due to changes in the surrounding environment. The CFAR may detect a target from a receiving signal based on a noise level and a threshold value corresponding to the surrounding environment.

As some embodiments, the processor 210 may calculate a distance to a target based on a frequency difference (i.e., a beat frequency) between a transmitting signal and a receiving signal, may calculate an angle to a target based on a phase difference between a transmitting signal and a receiving signal, and/or may calculate a velocity of a target based on the Doppler effect.

The RFIC 220 is configured to obtain one or more transmitting signals (e.g., one or more second signals) from a baseband signal, or to obtain a baseband signal from one or more receiving signals (e.g., one or more first signals) corresponding to one or more transmitting signals reflected from a target. In some embodiments, the RFIC 220 may include a transmission circuit 221 and a reception circuit 222. In some embodiments, the RFIC 220 may include the transmitting antennas TA1 to TAm, the transmission circuit 221, the receiving antennas RA1 to RAn, and the reception circuit 222.

The transmitting antennas TA1 to TAm are configured to transmit one or more transmitting signals, and the receiving antennas RA1 to RAn are configured to receive one or more receiving signals. For example, in some embodiments, one or more of the transmitting antennas TA1 to TAm and one or more of the receiving antennas RA1 to RAn may be implemented on a different substrate or a different chip than the RFIC 220.

The transmitting antennas TA1 to TAm and the receiving antennas RA1 to RAn may form an antenna array. For example, the transmitting antennas TA1 to TAm and/or the receiving antennas RA1 to RAn may operate according to beamforming.

The transmitting antennas TA1 to TAm may be configured with “m” transmitting antennas (where, “m” is a natural number), and the receiving antennas RA1 to RAn may be configured with “n” receiving antennas (wherein, “n” is a natural number that is the same as or different from “m”).

For example, when a radar system is supported in the RFIC 220, the transmitting antennas TA1 to TAm may transmit one or more transmitting signals toward a target, and the receiving antennas RA1 to RAn may receive one or more receiving signals corresponding to the one or more transmitting signals that have been reflected from the target. In this case, depending on the position or speed of the target, the receiving signals may have a time delay or a frequency variation due to the Doppler effect.

The transmission circuit 221 is configured to convert a digital signal generated or obtained from the processor 210 into a baseband signal and to process the baseband signal. According to some embodiments, the transmission circuit 221 may be configured to provide at least one of digital-to-analog (DA) conversion for the digital signal, frequency mixing (or, frequency up conversion) for the baseband signal, frequency modulation, filtering, or amplification. The transmission circuit 221 and the transmitting antennas TA1 to TAm may be included in a transmitter.

The reception circuit 222 is configured to convert one or more receiving signals received from receiving antennas RA1 to RAn into a baseband signal. According to some embodiments, the reception circuit 222 may include at least one of the low noise amplifier, the gain stage circuit, the mixer, the sink switch, the analog baseband circuit, or the ADC included in the embodiments illustrated in FIGS. 1 to 3 and FIGS. 5 to 9 described above. The reception circuit 222 and receiving antennas RA1 to RAn may be included in a receiver.

The electronic device 200 according to the embodiments described above may improve linearity for the receiving signal through the sink switch.

According to an embodiment of the present disclosure, a receiver with improved linearity and an electronic device including the same may be provided.

The above descriptions are various embodiments for carrying out the present disclosure. Embodiments in which a design is changed simply or which are easily changed may be included in the present disclosure as well as the various embodiment described above. In addition, technologies that are easily changed and implemented by using the above embodiments may be included in the present disclosure. Therefore, the scope of the present disclosure should not be limited to the above-described embodiments and should be defined by not only the claims to be described later, but also those equivalent to the appended claims of the present disclosure.

What is claimed is:

1. A receiver comprising:
a low noise amplifier;
a gain stage circuit configured to amplify an output of the low noise amplifier;
a first mixer coupled to the gain stage circuit through a first node and configured to perform frequency down conversion on an output of the gain stage circuit, based on a first local oscillator (LO) signal and a second LO signal inverted from the first LO signal;
a second mixer coupled to the gain stage circuit through a second node and configured to perform frequency down conversion on the output of the gain stage circuit, based on a third LO signal orthogonal to the first LO signal and a fourth LO signal inverted from the third LO signal;
a first sink switch coupled to the first node and configured to be turned on based on a first control signal defined as a sum of the third LO signal and the fourth LO signal; and
a second sink switch coupled to the second node and configured to be turned on based on a second control signal defined as a sum of the first LO signal and the second LO signal.

2. The receiver of claim 1, further comprising:
an analog baseband circuit configured to process a baseband signal corresponding to outputs from the first mixer and the second mixer; and
an analog-to-digital converter (ADC) configured to perform an analog-to-digital conversion on the baseband signal.

3. The receiver of claim 1, wherein the first sink switch is configured to be turned on when the first control signal is a logic high, and
the second sink switch is configured to be turned on when the second control signal is a logic high.

4. The receiver of claim 1, wherein, when the first sink switch is turned on, the first sink switch is configured to ground the first node, and
when the second sink switch is turned on, the second sink switch is configured to ground the second node.

5. The receiver of claim 1, wherein the first sink switch includes:
a first capacitor including:
a first terminal, and
a second terminal coupled to ground; and
a first N-type transistor including a first drain coupled to the first node, a first source coupled to the first terminal, and a first gate which is configured to receive the first control signal.

6. The receiver of claim 5, wherein the second sink switch includes:
a second capacitor including:
a third terminal, and
a fourth terminal coupled to ground; and
a second N-type transistor including a second drain coupled to the second node, a second source coupled to the third terminal, and a second gate which is configured to receive the second control signal.

7. The receiver of claim 1, wherein the gain stage circuit includes:
a first transconductance amplifier coupled to the first node; and
a second transconductance amplifier coupled to the second node.

8. The receiver of claim 1, wherein a first interval, a second interval, a third interval, and a fourth interval are consecutively included in a period defined for the first to fourth LO signals,
wherein the first LO signal has a logic high in the first interval,
wherein the second LO signal has a logic high in the third interval,
wherein the third LO signal has a logic high in the second interval, and
wherein the fourth LO signal has a logic high in the fourth interval.

9. The receiver of claim 1, wherein the first LO signal and the second LO signal are in-phase signals, and
wherein the third LO signal and the fourth LO signal are quadrature signals.

10. The receiver of claim 7, wherein the first transconductance amplifier includes:
two inverters, which are configured to receive the output of the low noise amplifier, are coupled to the first node, and include a ground terminal and a supply terminal;
two N-type transistors, each including a first drain coupled to the ground terminal, a first gate configured to receive a selection signal, and a first source that is grounded; and
two P-type transistors, each including a second drain coupled to the supply terminal, a second gate configured to receive an inverted selection signal that is inverted from the selection signal, and a second source configured to receive a supply voltage.

11. The receiver of claim 1, wherein the first mixer includes:
a third capacitor including a fifth terminal, which is coupled to the first node, and a sixth terminal;
a third N-type transistor including a first drain coupled to the sixth terminal, a first gate which is configured to receive the first LO signal, and a first source that outputs a baseband signal corresponding to the frequency down conversion;
a fourth N-type transistor including a second drain coupled to the sixth terminal, a second gate which is configured to receive the second LO signal, and a second source that outputs the baseband signal;
a fourth capacitor including a seventh terminal, which is coupled to the first node, and an eighth terminal;
a fifth N-type transistor including a third drain coupled to the eighth terminal, a fifth gate which is configured to receive the first LO signal, and a third source that outputs the baseband signal; and
a sixth N-type transistor including a fourth drain coupled to the eighth terminal, a fourth gate which is configured to receive the second LO signal, and a fourth source that outputs the baseband signal.

12. A receiver comprising:
a low noise amplifier;
a gain stage circuit configured to amplify an output of the low noise amplifier;
a mixer coupled to the gain stage circuit through a node and configured to perform frequency down conversion on an output of the gain stage circuit, based on a first local oscillator (LO) signal and a second LO signal inverted from the first LO signal; and
a sink switch coupled to the node and configured to be turned on based on a control signal that is complementary to the first LO signal and the second LO signal.

13. The receiver of claim 12, wherein the control signal is defined as a sum of a third LO signal that is orthogonal to the first LO signal and a fourth LO signal that is inverted from the third LO signal.

14. The receiver of claim 12, wherein the sink switch is configured to ground the node when the sink switch is turned on based on the control signal being a logic high.

15. The receiver of claim 12, wherein the sink switch includes:
a capacitor including:
a first terminal, and
a second terminal coupled to ground; and
an N-type transistor including a drain coupled to the node, a source coupled to the first terminal, and a gate which is configured to receive the control signal.

16. The receiver of claim 13, wherein a first interval, a second interval, a third interval, and a fourth interval are consecutively included in a period defined for the first to fourth LO signals,
wherein the first LO signal has a logic high in the first interval,
wherein the second LO signal has a logic high in the third interval,
wherein the third LO signal has a logic high in the second interval, and
wherein the fourth LO signal has a logic high in the fourth interval.

17. The receiver of claim 13, wherein the first LO signal and the second LO signal are in-phase signals, and
wherein the third LO signal and the fourth LO signal are quadrature signals.

18. An electronic device comprising:
one or more receiving antennas configured to receive one or more first signals;
a reception circuit configured to convert the one or more first signals into a baseband signal; and
a processor configured to process the baseband signal in a digital domain, and
wherein the reception circuit includes:
a low noise amplifier configured to receive the one or more first signals and amplify the one or more first signals;
a gain stage circuit configured to amplify an output of the low noise amplifier;
a mixer coupled to the gain stage circuit through a node and configured to perform frequency down conversion on an output of the gain stage circuit, based on a first local oscillator (LO) signal and a second LO signal inverted from the first LO signal; and
a sink switch coupled to the node and configured to be turned on based on a control signal that is complementary to the first LO signal and the second LO signal.

19. The electronic device of claim 18, further comprising:
one or more transmitting antennas configured to transmit one or more second signals; and
a transmitter configured to convert the baseband signal into the one or more second signals.

20. The electronic device of claim 18, wherein the control signal is defined as a sum of a third LO signal that is orthogonal to the first LO signal and a fourth LO signal that is inverted from the third LO signal.
